(19) United States
(12) Patent Application Publication
(10) Pub. No.: US 2026/0334298 A1
(43) Pub. Date: Oct. 22, 2026

(54) METHOD FOR PRODUCING AN ARRANGEMENT HAVING A HOUSING PART FOR RECEIVING A SEMICONDUCTOR ELEMENT AND HAVING A BASE PLATE

(71) Applicant: Siemens Aktiengesellschaft, München (DE)

(72) Inventors: Rainer Hüttner, Bamberg (DE); Ronny WERNER, Nürnberg (DE)

(73) Assignee: Siemens Aktiengesellschaft, München (DE)

(21) Appl. No.: 19/122,569

(22) PCT Filed: Aug. 10, 2023
(86) PCT No.: PCT/EP2023/072140

§ 371 Date: Apr. 18, 2025

(30) Foreign Application Priority Data
Oct. 20, 2022 (EP) 22202635.3

(51) Int. Cl. H10W 76/12; H10W 42/00

(52) U.S. Cl. CPC H10W 76/12; H10W 42/121

(57) ABSTRACT

In a method for producing an arrangement, a first housing component is formed and a pin with a wiring area is at least partially cast into a first plastic frame of the first housing component. A second housing component, which comprises a vibration-damping material, is inserted into the first housing component to form a housing part for receiving a semiconductor element. The vibration-damping material is brought into loose contact with a contact area on a wiring-area-opposite side of the first housing component. The housing part is connected to a base plate and the second housing component is brought into contact with the base plate.

The invention relates to a method for producing an arrangement having a housing part for receiving a semiconductor element and having a base plate.

The invention further relates to an arrangement having a housing part for receiving a semiconductor element and having a base plate.

In addition, the invention relates to a semiconductor module having at least one such arrangement.

Furthermore, the invention relates to a current converter having at least one such semiconductor module.

Moreover, the invention relates to a computer program product comprising Instructions which, when the program is executed on a computer, cause said computer to simulate a behavior, in particular a mechanical and/or electrical behavior, of such an arrangement.

Such an arrangement can be part of a semiconductor module which is conventionally deployed in a current converter. A current converter is understood to be, for example, an AC/DC converter, a DC/AC converter, an AC frequency converter or a DC/DC converter. The arrangement can be part of a housing for at least one semiconductor element. Such housings customarily comprise a plurality of housing parts, for example one or more housing frame parts, a housing floor plate which is also known as a base plate, and a housing cover. The individual housing parts are usually glued together, so that at least one semiconductor element, for example an Integrated circuit, is completely enclosed in the interior of the housing by the housing, Semiconductor elements that are used in such a semiconductor module can be inter alia transistors, diodes, triacs or thyristors. The transistors are embodied as insulated-gate bipolar transistors (IGBTs), field-effect transistors or bipolar transistors, for example. For the purpose of electrical contacting, provision is usually made for electrical contacts, so-called pins, which are directed out from the interior of the housing.

The unexamined patent application WO 2021/209186 A1 describes a semiconductor module having a housing, at least one semiconductor element, a first substrate and a second substrate. In order to specify a semiconductor module which is more compact, in comparison with the prior art, it is proposed to arrange at least the semiconductor element and the first substrate in the housing, the semiconductor element being connected to at least one pin in an electrically conductive manner, the at least one pin being in contact with the second substrate and being permanently connected within the housing, and the first substrate being connected in the manner of a non-positive fit in the housing via the least one pin.

Within such a housing, electrical connections can be produced inter alia by means of wire bonds. A common method in this case is ultrasound wire bonding, where a bonding wire and a bonding area are welded together by means of pressure and ultrasound vibrations. Vibrations that occur as a result of the bonding process during the ultrasound wire bonding of bonding areas of the pins can provoke undesired vibrations, for example due to resonances, such that a welded connection between the bonding wire and the bonding area of a pin is not produced or is not produced with the required quality.

An object of the present invention is therefore to provide a method that is as simple and cost-effective as possible for producing an arrangement which has both a housing part for receiving a semiconductor element and a base plate, and which allows reliable wiring.

This object is inventively achieved by a method for producing an arrangement having a housing part for receiving a semiconductor element and having a base plate, comprising the following steps: forming a first housing component, wherein at least one pin is at least partially cast into a first plastic frame, and wherein a wiring area is formed on the pin; inserting a second housing component, which comprises a vibration-damping material, Into the first housing component in order to form the housing part, wherein the vibration-damping material is brought into loose contact with a contact area that is arranged on an opposite side of the first housing component to the wiring area; connecting the housing part to the base plate, wherein the second housing component is brought into contact, in particular direct contact, with the base plate.

Furthermore, the object is inventively achieved by an arrangement having a housing part for receiving a semiconductor element and having a base plate, the housing part comprising a first housing component and a second housing component, the first housing component having at least one pin, the pin being at least partially cast into a first plastic frame, a wiring area being formed on the pin, the second housing component being inserted into the first housing component in order to form the housing part, the second housing component having a vibration-damping material, the vibration-damping material being in loose contact with a contact area which is arranged on an opposite side of the first housing component to the wiring area, and the housing part being connected to the base plate in such a way that that second housing component is in contact, in particular direct contact, with the base plate.

In addition, the object is inventively achieved by a semiconductor module having at least one such arrangement.

Furthermore, the object is inventively achieved by a current converter having at least one such semiconductor module.

Moreover, the object is inventively achieved by a computer program product comprising instructions which, when the program is executed on a computer, cause said computer to simulate a behavior, in particular a mechanical and/or electrical behavior, of such an arrangement.

The advantages and preferred embodiments cited below in respect of the method can be applied analogically to the arrangement, the semiconductor module, the current converter and the computer program product.

The invention proceeds from the notion of enabling a reliable wiring of a wiring area of at least one pin, which is at least partially cast into a first plastic frame of a first housing component, by damping vibrations that occur during the wiring process by means of a vibration-damping material. In this case, a housing part which consists of at least two parts is produced from a first housing component and a second housing component, the first housing component comprising a first plastic frame into which is cast at least one pin having a wiring area. For example, the first plastic frame is so designed as to be annular, in particular rectangularly annular, and is configured to completely surround a semiconductor element. In a further step, in particular following thereupon, a second housing component, which has a vibration-damping material, is inserted into the first housing component in order to form the housing part. The vibration-damping material can contain silicone, for example. The insertion can include a connection of the housing components, for example by means of a press fit. The vibration-damping material of the second housing component is in loose contact with a contact area of the first housing component, said contact area being arranged on an opposite side to the wiring area. In this context, a loose contact is understood to mean that the vibration-damping material is in contact with the contact area in a detachable manner, i.e. without a material-fit connection, for example, such as an adhesive connection, for example. The loose contact can include pressing-on of the vibration-damping material. For example, the silicone-containing vibration-damping material can be in contact with the contact area in a cured state. In a further step, in particular following thereupon, the housing part is connected to the base plate, the second housing component being in contact, in particular direct contact, with the base plate. As a result of the loose contact of the vibration-damping material with the contact area that is arranged on the opposite side to the wiring area, improved damping of vibrations that occur during the wiring process is achieved. Furthermore, the production process is simplified by the loose contact of the vibration-damping material, since the number of process steps is reduced. For example, neither a resource-intensive dispensing process nor a subsequent drying process is required. The production process is consequently simplified by means of the described method, and costs are saved by reducing the number of process steps.

A computer program product comprising instructions which, when the program is executed by a computer, cause said computer to simulate a behavior, in particular a mechanical and/or electrical behavior, of the described arrangement, can be called or comprise a “digital twin” or be designed as such. Such a digital twin is shown in the unexamined patent application US 2017/0286572A1. The disclosure of US 2017/0286572 A1 is included in the present application by virtue of cross-reference, The “digital twin” is, for example, a digital representation of the components that are relevant for the production and/or operation of the arrangement.

A further embodiment provides for the vibration-damping material to be in planar contact, in particular full-surface contact, with the contact area. As a result of the planar contact, in particular full-surface contact, of the vibration-damping material, vibrations that occur during the wiring process are damped in an optimal manner.

A further embodiment provides for at least one semiconductor element to be arranged on the base plate, the wiring area of the pin being wired to the semiconductor element after the housing part has been connected to the base plate, wherein vibrations that occur during the wiring of the wiring area are damped at least partially by the vibration-damping material. Wiring elements can be inter alla bonding wires or bonding strips which are welded, in particular by means of ultrasound wire bonds. Vibrations of such bond connections are damped in an optimal manner by the vibration-damping material.

A further embodiment provides for the at least one semiconductor element to be connected to the base plate in an electrically insulating and thermally conductive manner via a substrate before the housing part is connected to the base plate. The substrate can be embodied inter alla as a DCB (direct copper bonded) substrate. The semiconductor element is embodied as a vertical transistor, for example, in particular an IGBT or vertical SiC-MOSFET, such a connection via a substrate being both space-saving and cost-effective. For example, the wiring area of the at least one pin is wired to the substrate, the substrate being connected via a further wiring element to the semiconductor element. Alternatively, the wiring area of the at least one pin can be wired directly to the semiconductor element. By virtue of the sequence of the process steps, a production process having a small number of process steps is achieved.

A further embodiment provides for the connection of the housing part to be effected by means of a material-fit, in particular adhesive, connection of the first housing component and/or the second housing component to the base plate, For example, the first plastic frame or the second plastic frame of the housing part is adhesively connected to the base plate. In particular, an adhesive connection of the housing part to the base plate is cured under pressure. The damping effect of the vibration-damping material is only minimally influenced by such a material-fit connection.

A further embodiment provides for the second housing component to comprise a second plastic frame, on which the vibration-damping material is deposited, in particular circumferentially, before the insertion. For example, the second plastic frame is so designed as to be annular, in particular rectangularly annular, and is configured to completely surround a semiconductor element. In particular, depositing the vibration-damping material circumferentially allows optimal vibration damping. The second plastic frame allows a stable construction and simple connection, at the same time as satisfactory vibration damping.

A further embodiment provides for a non-positive fit connection to be produced between the housing components upon insertion of the second housing component. In particular, a non-positive fit connection is produced between the first plastic frame of the first housing component and the second plastic frame of the second housing component. Such a non-positive fit connection can be produced easily and cost-effectively by means of jamming, for example. Such a non-positive fit connection can simplify inter alla a subsequent adhesive process.

A further embodiment provides for the vibration-damping material to be embodied as a silicone layer, in particular a circumferential layer, which is deposited onto the second plastic frame by means of a screen printing method or via a dispenser and then cured, the cured silicone layer coming into contact, in particular planar contact, with the contact area when the second housing component is inserted, By virtue of such prior application, the cured silicone layer can be in loose contact or detachably in contact with the contact area, whereby improved damping of vibrations that occur during the wiring process is achieved. Furthermore, the production process is simplified by the loose contact of the vibration-damping material.

A further embodiment provides for the second housing component to be embodied as a vibration-damping frame which is produced from the vibration-damping material. For example, the vibration-damping frame can be embodied as an annular, in particular rectangularly annular silicone frame or rubber frame. As a result of using such a vibration-damping frame, the production process is simplified.

A further embodiment provides for a non-positive fit connection to be produced between the first housing component and the vibration-damping frame when the second housing component is inserted. Such a non-positive fit connection can be produced easily and cost-effectively by means of jamming, for example. Moreover, the non-positive fit connection simplifies the further production process.

The invention is described and explained in greater detail below with reference to the exemplary embodiments illustrated in the figures.

It is shown in:

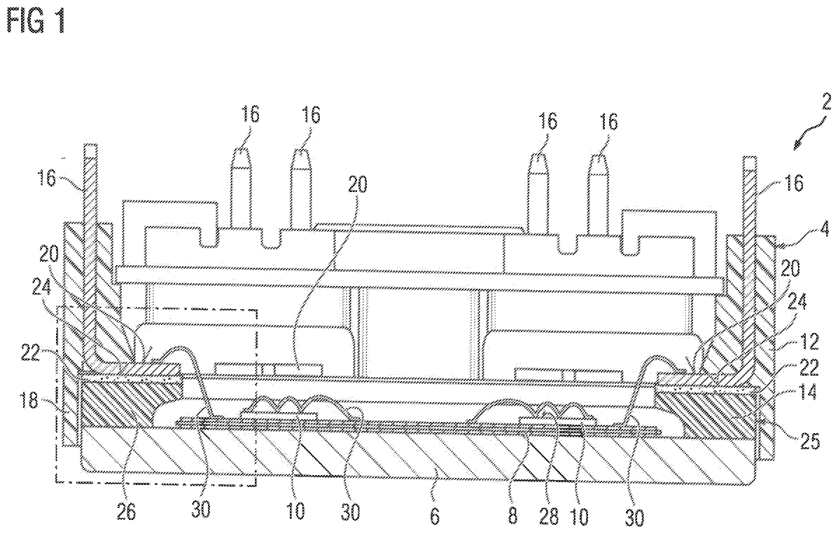

FIG. 1 a schematic sectional view of a first embodiment of an arrangement having a housing part and a base plate,

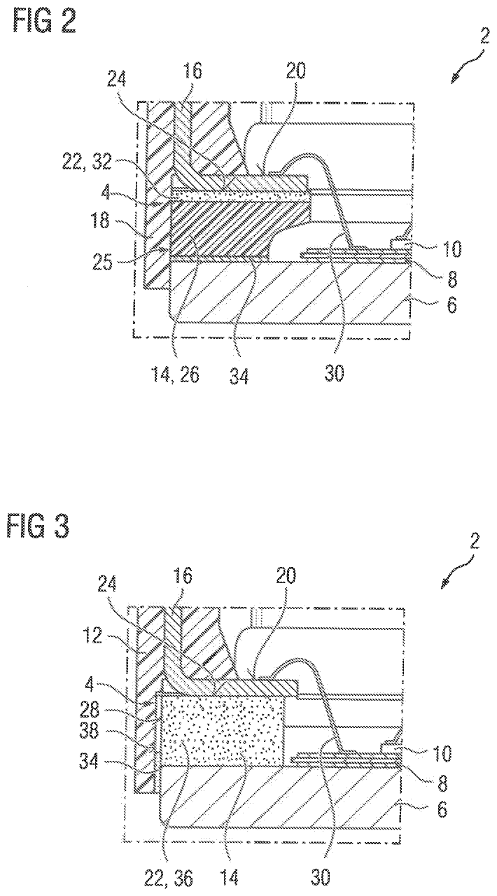

FIG. 2 an enlarged schematic sectional view of the first embodiment of the arrangement,

FIG. 3 an enlarged schematic sectional view of a second embodiment of an arrangement having a housing part and a base plate,

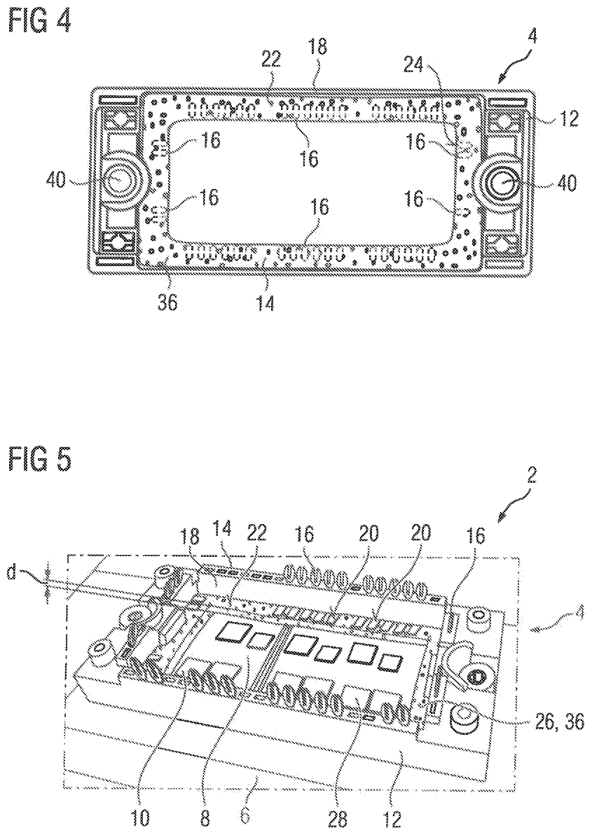

FIG. 4 a schematic illustration of a housing part in a plan view,

FIG. 5 a three-dimensional illustration of a third embodiment of an arrangement having a housing part and a base plate,

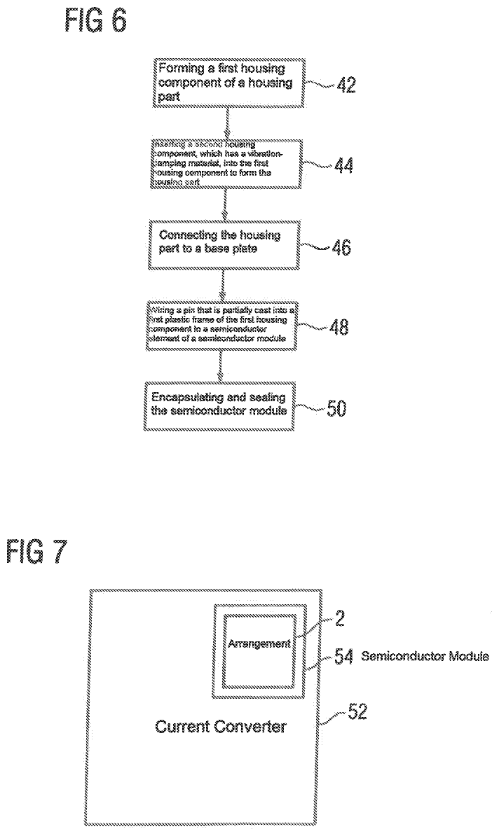

FIG. 6 a sequence diagram of a method for producing a semiconductor module,

FIG. 7 a schematic illustration of a current converter.

The exemplary embodiments explained in the following are preferred embodiment of the invention. In the exemplary embodiments, the components that are described in respect of the embodiment each represent individual and independent features of the invention, which also develop the invention independently of each other and must therefore also be considered, individually or in a combination other than that shown, as part of the invention. Furthermore, the embodiment described below can also be supplemented by further features described above in respect of the invention.

Identical reference signs have the same significance in the various figures.

FIG. 1 shows a schematic sectional view of a first embodiment of an arrangement 2 having a housing part 4 and a base plate 6. A substrate 8 onto which semiconductor elements 10 are connected by way of a material-fit is connected to the metallic base plate 6 on an opposite side to the semiconductor elements 10. The substrate 8 comprises a dielectric material layer, metalized on both sides, which contains a ceramic material, for example aluminum nitride or aluminum oxide, or an organic material such as a polyamide, for example. The dielectric material layer can have a thickness from 25 μm to 600 μm, in particular 50 μm to 320 μm. The semiconductor elements 10 can be embodied inter alia as transistors and/or diodes, in particular vertical transistors and/or diodes. A transistor can be embodied inter alia as an insulated-gate bipolar transistor (IGBT), a metal-oxide semiconductor field effect transistor (MOSFET) or a bipolar transistor. Furthermore, at least one transistor can be assigned a diode, in particular an antiparallel-connected diode. The material-fit connection of the semiconductor elements 10 to the substrate 8 can be produced inter alia by means of soldering and/or sintering.

The housing part 4 has a first housing component 12 and a second housing component 14, the first housing component 12 having a plurality of pins 16 which are configured for electrical connection to the substrate 8. The pins 16 are each partially cast into a first plastic frame 18 and project up from the plastic frame 18. A contacting region 17 of the pins 16 is configured to produce a connection to a board, for example a soldered connection or a press-fit connection. Furthermore, the pins 16 each comprise a wiring area 20, which can be embodied inter alla as a bonding area and which is configured to produce an electrical connection between the pin 16 and at least one of the semiconductor elements 10. The first plastic frame 18 in FIG. 1 is annular, in particular rectangularly annular, and surrounds the substrate 8 completely. The second housing component 14 is inserted into the first housing component 12 in order to form the housing part 4, said second housing component 14 being connected to the housing component 12 by way of a non-positive fit. For example, the second housing component 14 is jammed together with the first housing component 12 via an external surface 25. The second housing component 14 comprises a vibration-damping material 22 which can contain silicone, for example. The vibration-damping material 22 is in loose contact with a contact area 24 which is on an opposite side of the first housing component 12 to a wiring area 20. A loose contact is understood to mean that the vibration-damping material 22 is in contact with the contact area 24 in a detachable manner, I.e. without a material-fit connection such as an adhesive connection. The loose contact can include pressing-on of the vibration-damping material 22.

The second housing component 14 in FIG. 1 comprises a second plastic frame 26, which is annular, In particular rectangularly annular, in FIG. 1. The vibration-damping material 22 is circumferentially deposited on the second plastic frame 26 before this is inserted Into the first housing component 12. For example, the silicone of the vibration-damping material 22 can be connected to the contact area 24 in a detachable manner in its cured state, so that the vibration-damping material 22 lies loosely on the contact area 24 or is in contact by being loosely pressed on. For example, the second plastic frame 26 of the second housing component 14 is connected by way of a non-positive fit to the first plastic frame 18 of the first housing component 12 by means of jamming. Furthermore, the housing part 4 is connected to the base plate 6 in such a way that the second plastic frame 26 of the second housing component 14 is in direct contact with the base plate 6. For example, the housing part 4 is adhesively connected to the base plate 6.

The semiconductor elements 10 have semiconductor wiring areas 28 on an opposite side to the substrate 8. Wiring elements 30 are provided for the electrical connection of the pins 16 to the semiconductor elements 10. The wiring elements 30 can be embodied inter alla as bonding wires or bonding strips. In FIG. 1, wiring areas 20 of the pins 16 are connected to the substrate 8 via wiring elements 30, the substrate 8 being connected to the semiconductor wiring areas 28 via wiring elements 30. Alternatively, at least one wiring area 20 of a pin 16 can be connected directly to a semiconductor wiring area 28 via at least one wiring element 30. The wiring elements 30 are welded using an ultrasound wire bonding method, for example. Vibrations that occur during the production of the bond connection are at least partially damped by the vibration-damping material 22.

FIG. 2 shows an enlarged schematic sectional view of the first embodiment of the arrangement 2. The vibration-damping material 22 is embodied as a silicone layer 32 which is arranged circumferentially on the annular, in particular rectangularly annular, second plastic frame 26. The silicone layer 32 is deposited or applied onto the second plastic frame 26 by means of a screen printing method, a template printing method or by a dispenser. The silicone is cured before the second housing component 14 is inserted. By virtue of such prior application, the cured silicone layer 32 can be in loose contact or detachably in contact with the contact area 24. The silicone layer 32 can have a thickness in the range from 50 μm to 1 mm. The vibration-damping material 22 embodied as a silicone layer 32 is essentially in full-surface contact with the contact area 24, so that optimal vibration damping can be achieved. The housing part 4 is connected with a material fit to the base plate 6 by means of an adhesive connection 34 of the second plastic frame 26. The adhesive connection 34 is produced by means of a glue, for example, which is cured under pressure that is produced by pressing the housing part 4 onto the base plate. The further embodiment of the arrangement 2 in FIG. 2 corresponds to the embodiment in FIG. 1.

FIG. 3 shows an enlarged schematic sectional view of a second embodiment of an arrangement 2 having a housing part 4 and a base plate 6, the second housing component 14 of the housing part 4 being embodied as a vibration-damping frame 36 which is made of the vibration-damping material 22. For example, the vibration-damping frame 36 is embodied as an annular, in particular rectangularly annular, silicone frame or rubber frame, which has an essentially constant rectangular or square cross section along its length. The housing part 4 is connected to the base plate 6 by way of a material-fit so that an adhesive connection 34 is produced between the first plastic frame 18 and the base plate 6, The adhesive connection 34 to the base plate 6 is produced via an interior surface 38 of the first plastic frame 18, it being possible for a glue of the adhesive connection 34 to extend over at least part of an external surface 25 of the vibration-damping frame 36. By means of pressing the housing part 4 against the base plate, the glue is cured under pressure. The further embodiment of the arrangement 2 in FIG. 3 corresponds to the embodiment in FIG. 2.

FIG. 4 shows a schematic illustration of a housing part 4 in a plan view, the first housing component 12 comprising a rectangularly annular first plastic frame 18 in which pins 16 are partially cast in each case, The second housing component 14 of the housing part 4 is embodied as a vibration-damping frame 36 which is made of the vibration-damping material 22. For example, the vibration-damping frame 36 is embodied as an annular, in particular rectangularly annular, silicone frame, which can terminate flush with the contact areas 24 of the pins 16 or can project at least partially beyond the contact areas 24 of the pins 16. The silicone frame lies loosely on the contact areas 24 of the pins 16. Alternatively, the silicone frame in the cured state can be connected at least partially to the contact areas 24 of the pins 16 by means of an adhesive connection. Openings 40 that are embodied as threaded holes, for example, can be configured to press the housing part 4 onto a base plate (not shown in FIG. 4 for reasons of clarity) via a positive-fit connection, in particular a screw connection. The connection of the housing part 4 to the base plate takes place in a further step. The further embodiment of the housing part 4 in FIG. 4 corresponds to the embodiment in FIG. 3.

FIG. 5 shows a three-dimensional illustration of a third embodiment of an arrangement 2 having a housing part 4 and a base plate 6. The vibration-damping frame 36 is embodied as an annular, in particular rectangularly annular, silicone frame, which projects partially beyond the contact areas 24 of the pins 16 but which has an essentially circumferential distance d from the substrate 8 and lies in a planar manner on the base plate 6. Wiring of the pins 16 and the semiconductor elements 10 is not yet done in FIG. 5 and takes place in a further step. The further embodiment of the arrangement 2 in FIG. 4 corresponds to the embodiment in FIG. 3.

FIG. 6 shows a sequence diagram of a method for producing a semiconductor module which comprises a housing with a housing part for receiving a semiconductor element, at least one semiconductor element and a base plate, and whose production comprises forming 42 a first housing component of the housing part, in the course of which at least one pin that is configured for electrical connection to a substrate is at least partially cast into a first plastic frame, and in the course of which a wiring area is formed on the pin and is configured for producing an electrical connection between the pin and the semiconductor element.

A step following thereupon comprises inserting 44 a second housing component, which has a vibration-damping material, into the first housing component in order to form the housing part of the housing, in the course of which the vibration-damping material is brought into loose contact with a contact area that is arranged on an opposite side of the first housing component to the wiring area.

A step following thereupon comprises connecting 46 the housing part to the base plate, in the course of which a substrate is connected with a material bond to the base plate. The at least one semiconductor element is connected with a material bond to the substrate. In this context, the second housing component is brought into direct contact with the base plate. A direct contact includes the connection means for producing a material-fit connection, such as adhesives, but excludes additional connection elements such as spacers.

A further step comprises wiring 48 of the pins to the at least one semiconductor element, pins being connected to the substrate via wiring elements, for example, and the substrate being connected to the at least one semiconductor element via wiring elements. Alternatively, at least one pin can be connected directly to the at least one semiconductor element via at least one wiring element. The wiring elements are welded using an ultrasound wire bonding method, for example. Vibrations that occur during the wiring 48 are at least partially damped by the vibration-damping material.

A further step comprises encapsulating and sealing 50 the semiconductor module, The required voltage separations are satisfied by means of an encapsulating material which contains silicone, for example. Furthermore, such an encapsulation serves to protect against harmful environmental influences. The housing is sealed by a housing cover, this being connected to the housing part.

FIG. 7 shows a schematic illustration of a current converter 52 comprising a semiconductor module 54 which has an arrangement 2. The current converter 52 can comprise more than one semiconductor module 54. At least one semiconductor module 54 can comprise more than one arrangement 2.

In summary, the invention relates to a method for producing an arrangement 2 having a housing part 4 for receiving a semiconductor element 10 and having a base plate 6. In order to identify a production method which is as simple and cost-effective as possible and which allows reliable wiring, the following steps are proposed: forming 42 a first housing component 12, in the course of which at least one pin 16 is at least partially cast into a first plastic frame 18, and in the course of which a wiring area 20 is formed on the pin 16; inserting 44 a second housing component 14, which comprises a vibration-damping material 22, into the first housing component 12 in order to form the housing part 4, in the course of which the vibration-damping material 22 is brought into loose contact with a contact area 24 which is arranged on an opposite side of the first housing component 12 to the wiring area 20; connecting 46 the housing part 4 to the base plate 6, in the course of which the second housing component 14 is brought into contact, in particular direct contact, with the base plate 6.

1.-15. (canceled)

16. A method for producing an arrangement, the method comprising:
forming a first housing component with a pin which has a wiring area and which is at least partially cast into a first plastic frame of the first housing component;
inserting a second housing component, which comprises a vibration-damping material, into the first housing component to form a housing part for receiving a semiconductor element;
loosely contacting the vibration-damping material with a contact area on a wiring-area-opposite side of the first housing component;
connecting the housing part to a base plate; and
contacting the second housing component with the base plate.

17. The method of claim 16, wherein the second housing component is brought into direct contact with the base plate.

18. The method of claim 16, wherein the vibration-damping material is in planar contact with the contact area.

19. The method of claim 16, wherein the vibration-damping material is in full-surface contact with the contact area.

20. The method of claim 16, further comprising:
arranging the semiconductor element on the base plate; and
after connecting the housing part to a base plate, wiring the wiring area of the pin to the semiconductor element, with vibrations that occur during wiring of the wiring area being at least partially damped by the vibration-damping material.

21. The method of claim 20, further comprising connecting the semiconductor element to the base plate in an electrically insulating and thermally conductive manner via a substrate before the housing part is connected to the base plate.

22. The method of claim 16, wherein the housing part is connected by a material-fit, in particular adhesive connection, of the first housing component and/or the second housing component to the base plate.

23. The method of claim 16, further comprising depositing the vibration-damping material on a second plastic frame of the second housing component before the second housing component is inserted into the first housing component.

24. The method of claim 23, wherein the vibration-damping material is deposited circumferentially on the second plastic frame.

25. The method of claim 16, further comprising producing a non-positive fit connection between the first and second housing components, as the second housing component is inserted into the first housing component.

26. The method of claim 23, wherein the vibration-damping material is embodied as a silicone layer, in particular a circumferential layer, and deposited onto the second plastic frame, by a screen printing method or via a dispenser, the method further comprising:
allowing the silicone layer to cure; and
contacting the cured silicone layer, in particular by planar contact, with the contact area when the second housing component is inserted into the first housing component.

27. The method of claim 16, further comprising producing the second housing component as a vibration-damping frame made from the vibration-damping material.

28. The method of claim 27, further comprising producing a non-positive fit connection between the first housing component and the vibration-damping frame, as the second housing component is inserted into the first housing component.

29. An arrangement, comprising:
a housing part designed to receive a semiconductor element and comprising a first housing component and a second housing component which is inserted into the first housing component in order to form the housing part, said first housing component including a pin which is at least partially cast into a first plastic frame of the first housing part and has formed thereon a wiring area, said second housing component including a vibration-damping material which is in loose contact with a wiring-area-opposite contact area of the first housing component; and
a base plate,
wherein the housing part is connected to the base plate in such a way that the second housing component is in contact with the base plate.

30. The arrangement of claim 29, wherein that the second housing component is in direct contact with the base plate.

31. The arrangement of claim 29, wherein the vibration-damping material is in planar contact, in particular full-surface contact, with the contact area.

32. The arrangement of claim 29, wherein the vibration-damping material is in full-surface contact with the contact area.

33. A semiconductor module, comprising:
a semiconductor element; and
an arrangement comprising a housing part designed to receive the semiconductor element and comprising a first housing component and a second housing component which is inserted into the first housing component in order to form the housing part, said first housing component including a pin which is at least partially cast into a first plastic frame of the first housing part and has formed thereon a wiring area, said second housing component including a vibration-damping material which is in loose contact with a wiring-area-opposite contact area of the first housing component, the arrangement further comprising a base plate, wherein the housing part is connected to the base plate in such a way that the second housing component is in contact with the base plate.

34. A current converter, comprising the semiconductor module of claim 33.

35. A computer program product, comprising a computer program embodied on a non-transitory computer readable medium comprising instructions which, when the computer program is executed by a computer, cause the computer to simulate a behavior, in particular a mechanical and/or electrical behavior, of the arrangement of claim 29.
